(19) United States
(12) Patent Application Publication
(10) Pub. No.: US 2014/0029200 A1
(43) Pub. Date: Jan. 30, 2014

(54) HIGH VOLTAGE POWER SUPPLY SYSTEM AND METHOD

(71) Applicants: Marc A. Annacchino, Greenfield, WI (US); Norman C. Lindner, Lake Wylie, SC (US); Michael Trumbower, Fort Wayne, IN (US)

(72) Inventors: Marc A. Annacchino, Greenfield, WI (US); Norman C. Lindner, Lake Wylie, SC (US); Michael Trumbower, Fort Wayne, IN (US)

(21) Appl. No.: 13/639,563

(22) PCT Filed: Oct. 15, 2010
(86) PCT No.: PCT/US10/52821

§ 371 Date: Oct. 15, 2013

Related U.S. Application Data
(60) Provisional application No. 61/354,350, filed on Jun. 14, 2010.

(51) Int. Cl. H05K 7/20

(52) U.S. Cl. CPC H05K 7/20318
USPC 361/700; 361/699

(57) ABSTRACT

A high voltage alternator feeding power electronics and then one or more magnetic components to create a high current low voltage power system includes a substrate/buss plate performs heat extraction and electrical termination. The system includes a substrate (102) having a fluid passage member (106) disposed at least partially between the substrate. Power electronic and magnetic circuits (104) are operable to convert a high voltage, low current signal to a plurality of lower voltage signals having distinct voltage and/or current characteristics from the high voltage, low current signal. The power electronic and magnetic circuits include a plurality of connectors that are configured to be received by the receiving ports (124) of the substrate such that the plurality of connectors are configured to provide an electrical connection between the one or more power electronic circuits and establish a thermal connection between the fluid passage member and the one or more power electronic circuits to provide thermal relief to the one or more power electronic circuits.

### RELATED APPLICATION DATA

The present application claims the benefit of the filing date of U.S. Provisional Patent Application Ser. No. 61/321,656 filed Apr. 7, 2010 and U.S. Provisional Patent Application Ser. No. 61/354,350, filed Jun. 14, 2010, which are incorporated herein by reference in their entirety.

### TECHNICAL FIELD

The present invention relates to a high voltage power supply system for vehicles including an electronics cooling system. The power supply system provides a more efficient and flexible system to meet the increasing need of specialized vehicles than conventional systems.

### BACKGROUND

Generator size in military vehicles is increasing. A main thrust behind this driven need is the addition of more Command, Control, Communications, Computers, Intelligence, Surveillance, Reconnaissance (C4ISR) Systems and also to bring electrical power to the war zone for command posts, tent cities and other uses. In general, the electronics content of military vehicles is skyrocketing with IED jammers and other equipment. Power needs can no longer be handled by simply supplying a larger conventional alternator or DC Generator. The trend is to incorporate either a transmission mounted alternator (High Voltage) or a belt driven alternator and using power conversion electronics to bring this to a usable level for protective and other equipment. With weight and efficiency requirements, traditional methods of DC power generation simply have exceeded practical limits in terms of belting, sheeves, mounting arrangements etc. Such systems also require conventional and non-conventional cooling and heat extraction techniques for equipment and passenger protection.

### SUMMARY

One aspect of the invention provides a power generation system comprising: an internal combustion engine; a permanent magnet generator; an AC/DC inverter; a DC/AC inverter; a transformer; a rectifier; and a cooling system that may include a pump for forcing a two phase refrigerant through a cold plate for cooling the AC/DC inverter, the DC/AC inverter, the transformer, and the rectifier, wherein the refrigerant passes through a condenser to reject heat and the refrigerant is returned to the pump.

The present invention overcomes the above deficiencies by providing an efficient method of cooling power electronics in a power conversion system for mobility and miniaturizing the system. One aspect of the invention relates to a substrate (also referred to herein as a “buss plate”) that provides two integrated functions: heat extraction integrated with electrical termination and interconnection of transformer or magnetics along with rectification cooling and interconnects.

One aspect of the invention relates to a power conversion system including: a substrate including a front surface a back surface, and a fluid passage member disposed at least partially between the front surface and the back surface, wherein the fluid passage member includes an inlet port for receiving fluid and an outlet port for outputting fluid, wherein the substrate includes a plurality of receiving ports for coupling one or more circuits to the substrate and the receiving ports are in fluid communication with the fluid passageway; and one or more power electronic circuits, wherein the one or more power electronic circuits include a plurality of connectors that are configured to be received by the receiving ports of the substrate such that the plurality of connectors are configured to provide an electrical connection between the one or more power electronic circuits and establish a thermal connection between the fluid passage member and the one or more power electronic to provide thermal relief to the one or more power electronic circuits.

Another aspect of the invention relates to a method for manufacturing a portable power supply, the method including: forming a fluid passageway with a fluid passage member housed at least partially within a substrate having a front surface and a back surface, wherein the fluid passage member includes an inlet port for receiving fluid and an outlet port for outputting fluid and the substrate includes a plurality of receiving ports that are in fluid communication with the fluid passageway; securing one or more power electronic and magnetic circuits to at least one of the receiving ports, wherein the electronic and/or magnetic circuits form an electrical connection and a thermal connection with the receiving ports; and placing the substrate containing the fluid passageway and the one or more power electronic and magnetic circuits within a housing that is configured to at least partially enclose the substrate and the one or more power electronic and magnetic circuits, wherein the inlet port and the outlet port are accessible through the housing.

Another aspect of the invention relates to a method for converting power, the method includes: receiving a high voltage, low current signal from a source; converting the high voltage, low current signal through one or more power electronic and magnetic circuits to a plurality of lower voltage signals having distinct voltage and/or current characteristics from the high voltage, low current signal, wherein the one or more power electronic and magnetic circuits are coupled to a substrate having a front surface a back surface, and a fluid passage member disposed at least partially between the front surface and the back surface, wherein the fluid passage member includes an inlet port for receiving fluid and an outlet port for outputting fluid, wherein the substrate includes a plurality of receiving ports for coupling the power electronic and magnetic circuits to the substrate and the receiving ports are coupled to the fluid passageway; and wherein the one or more power electronic and/or magnetic circuits include a plurality of connectors that are configured to be received by the receiving ports of the substrate such that the plurality of connectors are configured to provide an electrical connection between the one or more power electronic circuits and establish a thermal fluid connection between the fluid passage member and the one or more power electronic and magnetic circuits; and cooling the one or more power electronic and magnetic circuits by providing a cooling system utilizing a vaporizable dielectric refrigerant, wherein a pump forces vaporizable dielectric refrigerant through the fluid passageway of the substrate and the plurality of connectors.

Other systems, devices, methods, features, and advantages of the present invention will be or become apparent to one having ordinary skill in the art upon examination of the following drawings and detailed description. It is intended that all such additional systems, methods, features, and advantages be included within this description, be within the scope of the present invention, and be protected by the accompanying claims.

It should be emphasized that the term “comprise/comprising” when used in this specification is taken to specify the presence of stated features, integers, steps or components but does not preclude the presence or addition of one or more other features, integers, steps, components or groups thereof.”

### BRIEF DESCRIPTION OF THE DRAWINGS

Embodiments of this invention will now be described in further detail with reference to the accompanying drawings, in which:

FIG. 1 is an exemplary vehicle in accordance with aspects of the present invention.

FIGS. 2-4 are a schematic of a portion of exemplary high voltage power systems in accordance with aspects of the present invention.

FIG. 5 is a schematic of a high voltage power system in accordance with aspects of the present invention.

FIGS. 6A-6C is a perspective and cross-sectional views of an exemplary substrate in accordance with aspects of the present invention.

FIGS. 7-10 are schematic views of a portion of exemplary high voltage power systems in accordance with aspects of the present invention.

FIG. 11 is perspective and cross-section view of dielectric union in accordance with aspects of the present invention.

FIG. 12 is a schematic of an embodiment showing components packaged in interconnected sealed cast aluminum enclosures in accordance with aspects of the present invention.

FIG. 13 is a schematic of an embodiment showing back to back inverters in accordance with aspects of the present invention.

FIG. 14 is schematic view of the cooling system in accordance with aspect of the present invention.

FIGS. 15A-15C is a schematic view of one or more toroids and an encapsulation technique in accordance with aspects of the present invention.

FIG. 16 is a cross-section view of power electronics and magnetic circuits coupled to the substrate in accordance with aspects of the present invention.

### DETAILED DESCRIPTION OF EMBODIMENTS

The present invention provides a more efficient method of power generation for mobile and miniaturized power generation systems over conventional systems. In general, the system may be characterized by a high voltage alternator feeding power electronics and one or more magnetic components to create a high current low voltage power system. A substrate/buss plate is disclosed herein that performs two integrated functions: heat extraction and electrical termination for the power electronics and the magnetic components.

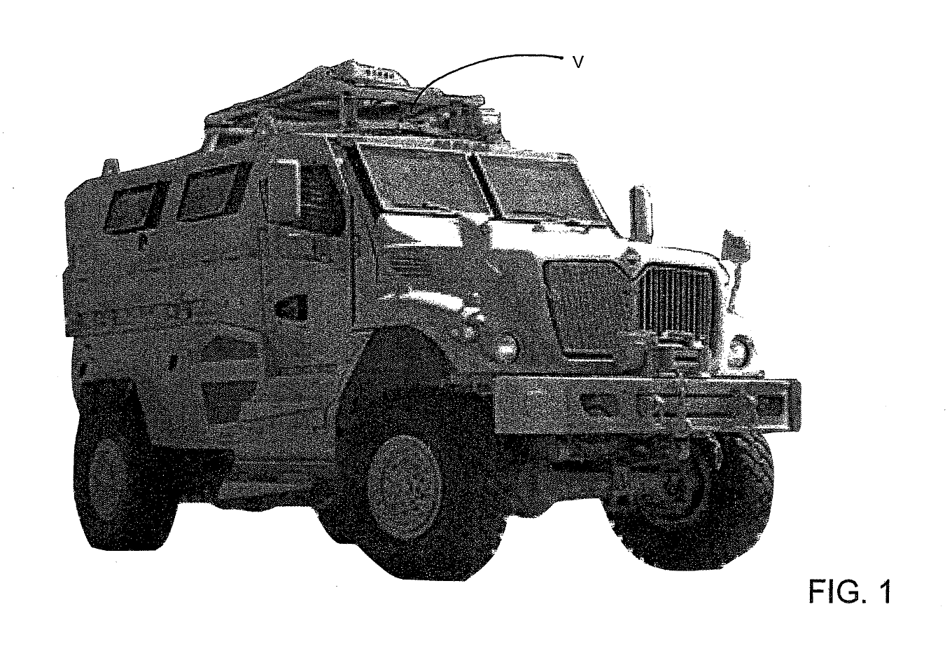

An exemplary vehicle (V) in accordance with aspects of the present invention is illustrated in FIG. 1. The vehicle (V) includes a power generation system to provide (export) power to other electrical devices in a mobile environment. A person having ordinary skill in the art will appreciate that the vehicle (V) is exemplary in nature and any vehicle may be used in accordance with aspects of the present invention.

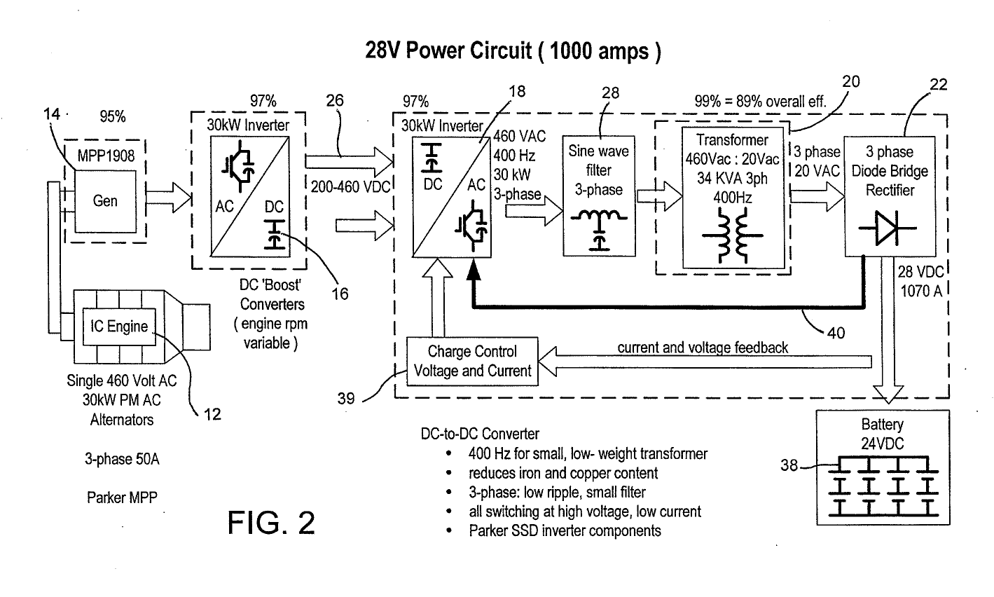

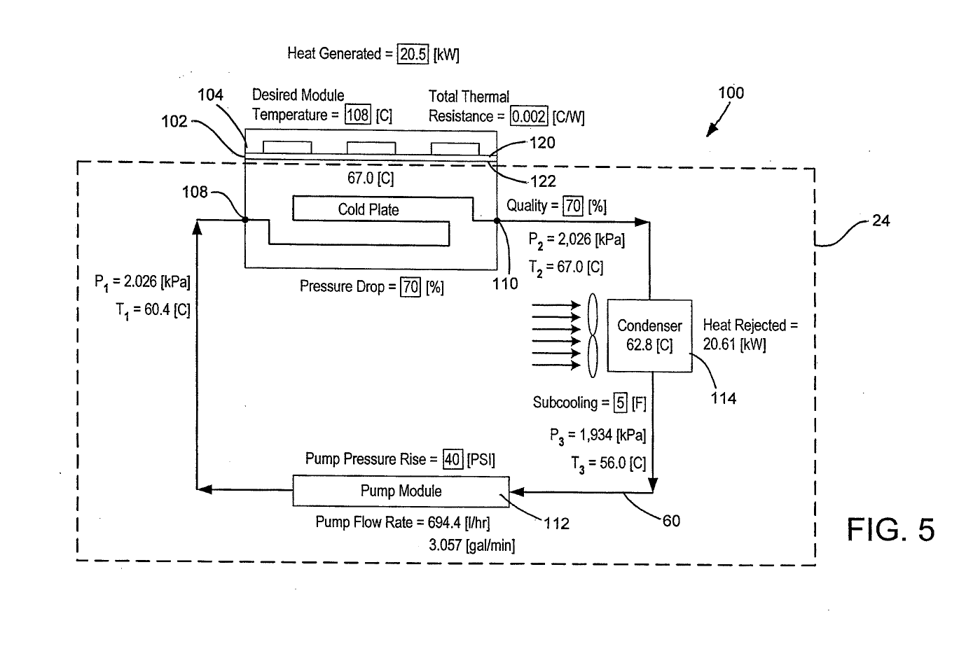

Referring to FIGS. 2-5, exemplary power generation systems 10 are illustrated that rely on an internal combustion engine 12 and an alternator 14 of the vehicle (V). In one embodiment, the power generation systems include the following power electronics and magnetic circuits: permanent magnet generator 14, AC/DC inverter 16, DC/AC inverter 18, transformer 20, rectifier 22. As explained below, the system 10 further includes a cooling system 24 (FIG. 5) that provides a mechanism to cool (e.g., transfer thermal energy from) various power electronics and magnetic circuits of the system.

The internal combustion engine 12 may be any suitable engine. For example, the internal combustion engine may be an engine designed for use in vehicles. As illustrated in FIG. 2, the internal combustion engine 12 may provide power to a permanent magnet generator 14. The permanent magnet generator 14 may be powered at 600 VAC or another suitable voltage. The AC/DC inverter 16 transforms the output (e.g., Volts AC) of the permanent magnet generator 14 to a stable DC level. For example, the AC/DC inverter 16 may convert the 600 VAC to a 635 VDC nominal signal. Such a transformation may be an active transformation using active power devices in the AC/DC inverter 16. The DC buss 26 may feed the DC/AC inverter 18 for conversion from the DC buss to AC Voltage operating at a desired VAC level (e.g., 480 VAC). The use of the first conversion allows the DC buss 26 to be created by AC/DC inverter 16 and regulated within the operating range of the vehicle engine 12 and the permanent magnet generator 14. This creates a stable buss voltage whether the vehicle engine 12 is operating at idle or at speed (e.g., the buss voltage is above a nominal voltage when the engine is a normal active state regardless of the RPM of the motor). This feature cannot be accomplished with traditional methods as the generator output varies with speed. The output of the DC/AC inverter 18 may feed an optional sine wave filter 28, if required, for smoothing out the waveform, to create a clean AC waveform.

The AC waveform is fed (from inverter 18 and/or sine wave filter 28) to a transformer 20. The transformer 20 may be, for example, a Wye connected center-tapped transformer having a delta primary with 6-phase secondary bridge rectifier. One of ordinary skill in the art will appreciate that other types of transformers may be used in accordance with aspects of the present invention. The output waveform of the DC/AC inverter 18 and/or sine wave filter 28 is powered at a frequency of 400 hertz. The primary tap of the transformer is input to the transformer 20, which converts the 480 VAC to 20 VAC that when rectified by rectifier 22 will produce 28 VDC at 400 Hz or other desirable output voltage. The illustrated system may be used to produce 28 volt, 1000 amp, 30 Kw system, which may be output to a battery 38 or other suitable device.

As shown in FIG. 2, a feedback loop 40 exists from the output of the system back to the inverter 18 through a charge control unit 39. The feedback loop 40 controls the voltage regulation under various loads and conditions. For example, the feedback loop 40 positioned between the rectifier 22 and the inverter 18 may be used to control the 28 volt DC signal for voltage and current stability. This closed loop feedback system far exceeds the performance of conventional generator/regulator combinations and completes the final regulation protocol for producing a stable output over a varying engine speed range.

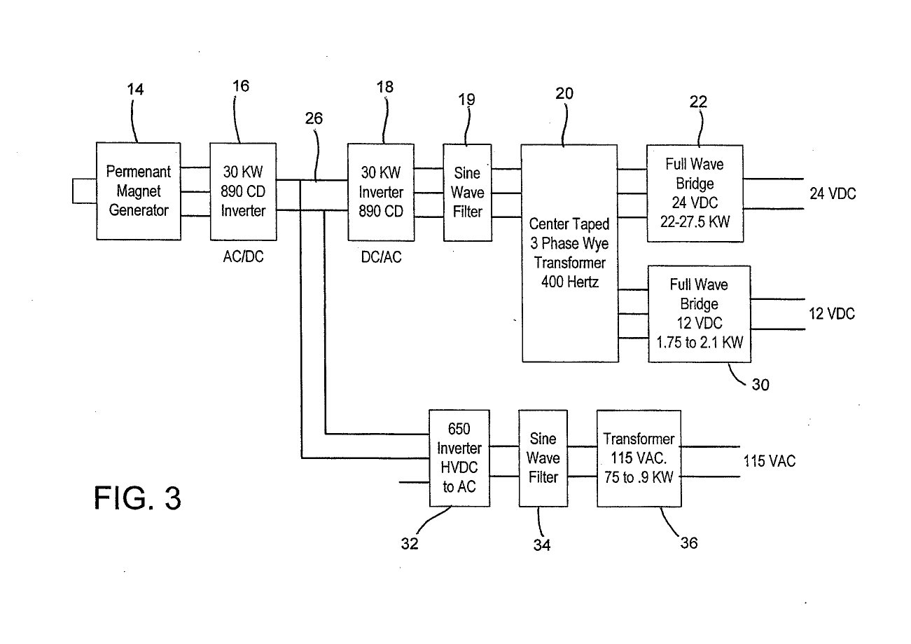

Referring to FIG. 3, another tap for the transformer 20 may be provided for another DC voltage, which when rectified by rectifier 30 will produce 12 VDC or any desired voltage, as illustrated by rectifier 30. As shown in FIG. 3, the output of the transformer 20 is fed to a rectifier 22 and 30, which transforms the AC voltage to a DC level. Still referring to FIG. 3, another voltage source may be derived from the DC buss 26, through an inverter 32. The inverter 32 may convert the DC buss signal 26 to an AC signal. An optional sine wave filter 34, which functions identically to sine wave filter 28, may couple signals generated by the inverter 32 to the transformer 36. As shown in FIG. 3, the transformer 36 may be configured to output a 115V AC signal. Thus, the system 10 illustrated in FIG. 3 may be configured to provide power sources for a plurality of devices having diverse power requirements.

Once a stable DC buss 26 is established, other inverters can be used to generate different voltages and powers required for the vehicle needs or devices that require power from the vehicle. The diagram of FIG. 3 is a typical example in which multiple voltages and powers may be output for vehicle needs or other needs. It is anticipated that this can also become part of a hybrid system for either export power or eventually traction by incorporating batteries either at the low voltage side or the high voltage buss depending on what the designer is attempting to accomplish as shown in FIG. 3.

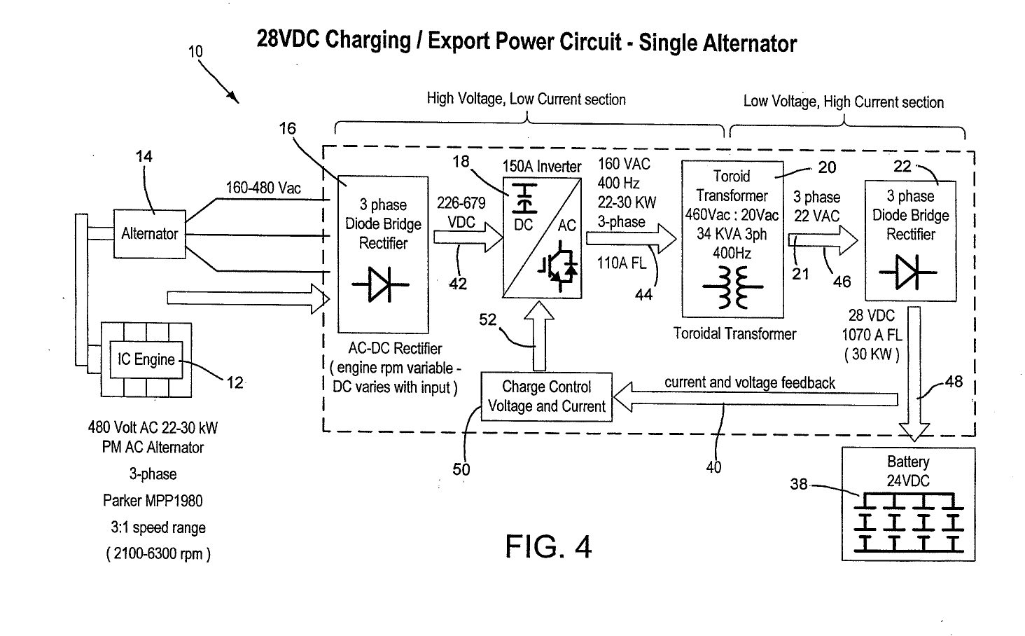

Another embodiment of the system 10 is illustrated in FIG. 4. In FIG. 4, engine 12 turns an alternator 14. The engine 12 and alternator 14 are identical to the engine and alternator discussed above. The alternator 14 outputs a 160-480 V alternating current signal to an AC-DC rectifier 16. For example, the AC-DC rectifier 16 may be a three phase diode bridge rectifier. The rectifier 16 outputs a DC voltage signal 42, which is variable based on engine rpm. Thus, the DC voltage signal 42 of the bridge rectifier 16 varies based on input. For example, the DC voltage signal 42 is coupled to an inverter 18. The inverter 18 outputs an AC signal 19 at a nominal 160 VAC at 400 Hz with 22-30 KW. The inverter 18 may be a MaxPlusPlus (MPP) 1908 manufactured by the assignee of the present application, for example.

The AC signal 44 is coupled to a transformer 20. The transformer 20 may be a toroid transformer. Toroid transformers are electronic components, typically consisting of a circular ring-shaped magnetic core of iron powder, ferrite, or other material around which wire is coiled to make an inductor. One benefit of a toroid transformer is that the magnetic flux in a toroid is largely confined to the core, preventing its energy from being absorbed by nearby components, which makes toroidal cores essentially self-shielding. In one embodiment, the toroid transformer is a three-phase transformer that receives 160 VAC at 400 Hz and converts the received signal to 22 VAC at 400 Hz (at 34 kV). The toroid transformer illustrated in FIG. 4 may be comprised of one or more separate toroid transformers. The inverter 18, which feeds transformer 20, constructs the waveform at this 400 Hz frequency for eventual form factor improvement of the waveform and also the availability of components and efficiency of operating magnetic at 400 HZ.

The secondary winding from the toroid transformer 20 may be used for dual purposes. For example, the secondary windings may be used to connect them electrically to a combination buss plate/substrate that has the electrical buss connections such that the secondary winding are interconnected to provide maximum secondary current from the transformer, as discussed below. In addition, the secondary windings may be used to fasten the secondary connections with the shortest possible length of copper to the substrate. This can be accomplished by welding the terminations to the substrate/buss plate. The substrate/buss plates then may extract the heat form the toroids via the secondary winding copper. An alternative method would be to extract heat from the core of the toroid and couple it to the substrate with thermal potting compound or RTV Material that conducts heat, as discussed below.

The transformer 20 outputs a signal 46 to a bridge rectifier 22. The bridge rectifier 22 may be identical to the bridge rectifier 22 discussed above. The output signal 48 of the bridge rectifier may be stored in a battery 38, capacitor or other energy storage medium. In addition, the signal 48 may be used for current and voltage feedback to a charge controller 50, which monitors voltage and current of the signal 23 and inputs a control signal 52 to the inverter 18 to provide closed loop control, in a similar manner as discussed with respect to feedback loop 40.

To accomplish the power levels, several of the power electronic and/or magnetic components need to have heat extracted from them. Such components may include, for example: the permanent magnet generator 14, the AC/DC inverter 16, DC/AC inverters 18, 18′, transformers 20, 120, and the rectifier 22. By utilizing cooling system 24, the components can be coupled to cooling plates or can be integrated into the various packages.

FIG. 5 illustrates an exemplary system 100 in accordance with aspects of the present invention. A substrate 102 (also referred to herein as a buss plate or cold plate) is illustrated having one or more power electronics and/or magnetic circuits 104 disposed on a surface of the substrate. A fluid passage member 106 generally exists at partially within the substrate 102. The fluid passage member 106 has an inlet port 108 and an outlet port 110. For purposes of clarity, the fluid passage member is illustrated extending below the substrate 102. The system 100 further includes pump module 112 and a condenser 114. In operation, refrigerant is pumped through the fluid passage member 106, to transfer heat generated from the circuits 104 to the condenser 114. The cooling system 24 is identified in dashed lines in FIG. 5.

The substrate 102 includes a first surface 120 a second surface 122. The fluid passage member 106 disposed at least partially between and/or across the first surface 120 and the second surface 122. The fluid passage member 106 includes an inlet port 108 for receiving fluid (e.g., refrigerant) and an outlet port 110 for outputting the fluid, for example, to condenser 114 for cooling the refrigerant.

The power electronics and/or magnetic circuits 104 are coupled to the substrate 102. The circuits 104 may be coupled to either or both surfaces 120, 122 of the substrate 102.

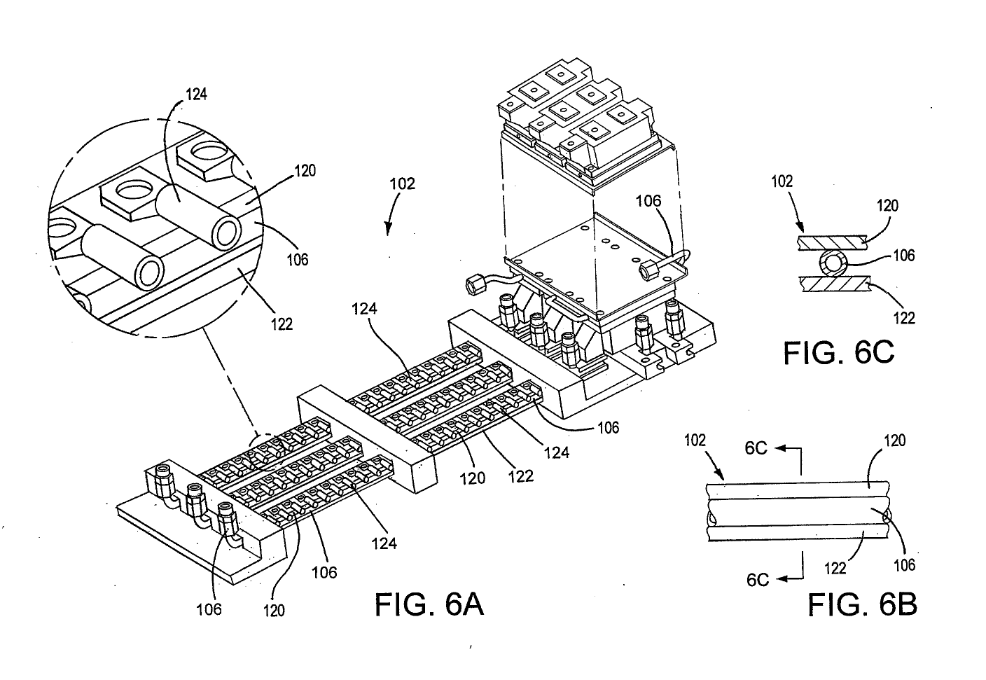

Referring to FIGS. 6A-6C, an exemplary substrate 102 is illustrated. The substrate 102 has a plurality of receiving ports 124 for coupling one or more circuits 104 to surface 120, 122 of the substrate 102. The receiving ports 124 form a connection to the fluid passage member 106 such that thermal energy may be transferred from the electrical components through the receiving ports 124 and an electrical connection to one or more other circuits. For example, the fluid passage member 106 illustrated in FIG. 6A is routed between the first surface 120 and second surface 122, such that all circuits 104 may be cooled and electrically connected, as desired. FIG. 6B illustrates a side view of the substrate 102, wherein the substrate has a first surface 120 and a second surface 122 and a fluid passage member 106 disposed partially between the surfaces 120, 122. FIG. 6C illustrates a cross-sectional view of the substrate 102.

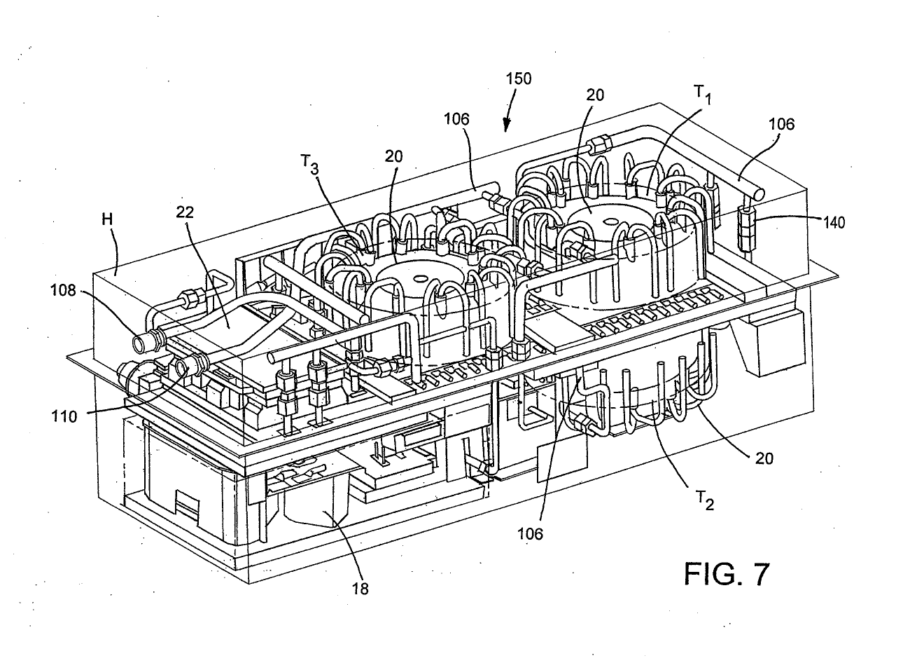

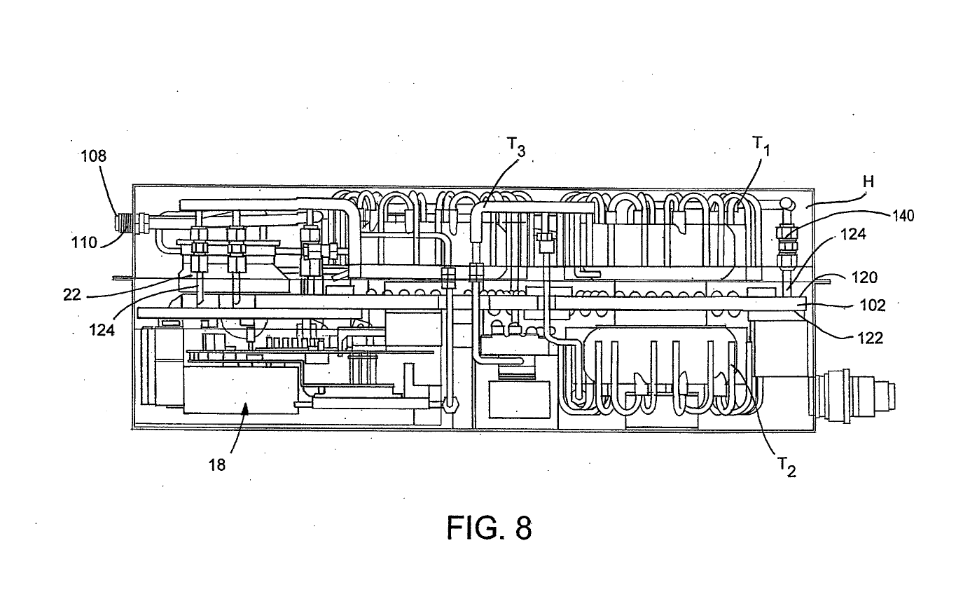

FIGS. 7-10 illustrate additional embodiments of the present invention. The transformer 20 is illustrated in FIGS. 7 and 8 as three separate toroid transformers (T1, T2 and T3). As discussed above, the toroids transform 480 VAC at 400 Hertz, down to 22 VAC at 400 HZ. The inverter 18, which feeds the transformer 20 constructs the waveform at this frequency for eventual form factor improvement of the waveform and also the availability of components and efficiency of operating magnetic at 400 HZ. The three toroids have numerous secondary winding terminations, because of their current carrying capacity and the fact that the transformer generally needs to be split up into multiple secondary windings. As shown in FIG. 7, two toroids (T1 and T2) are mounted and terminated to each side of the buss plate 102 with the third toroid (T3) mounted on an opposing side of inverter 18. One of ordinary skill will readily appreciate that the arrangement of components is exemplary in nature and not intended to limit the scope of the attached claims.

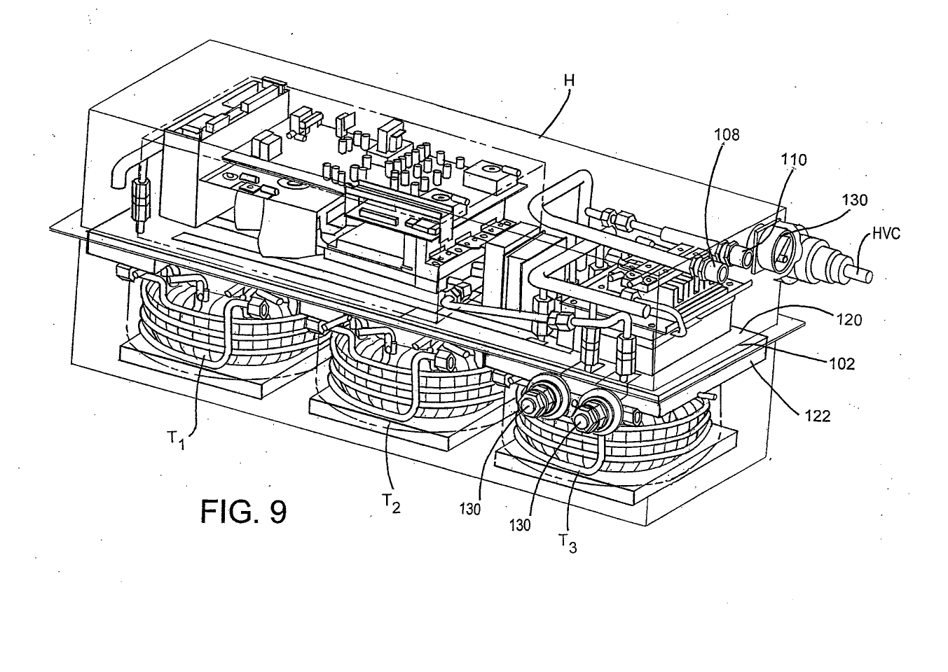

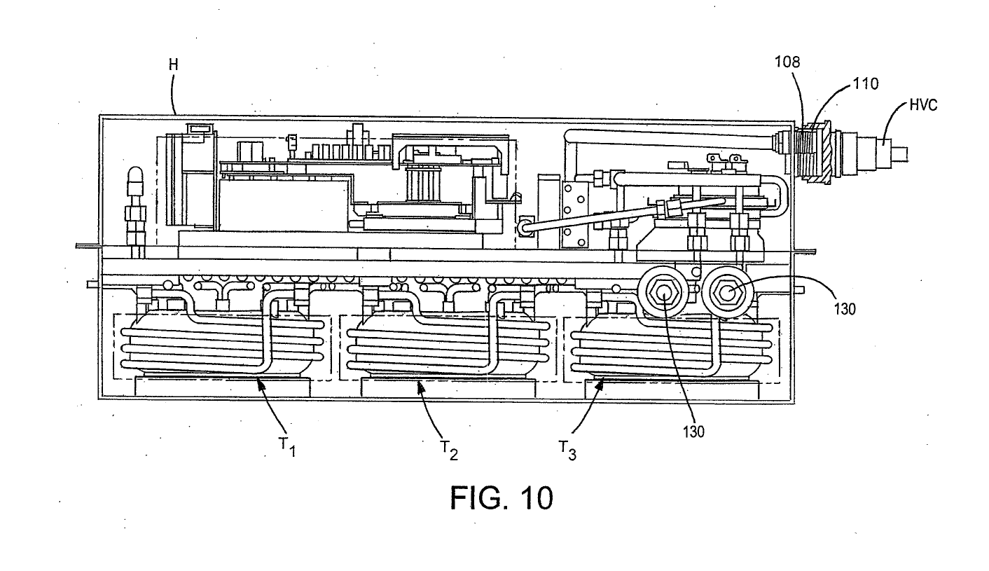

Referring to FIGS. 9 and 10, another embodiment of the system 100 is illustrated. As illustrated, the circuits 104 have been re-arranged to yield a more efficient arrangement. As shown in FIGS. 9 and 10, toroid transformers (T1, T2 and T3) have been placed on a common surface 122 of the substrate 102. Such an arrangement simplifies connecting the fluid passage member 106 to each of the components of the circuit 104.

The circuits 104 are highly configurable to perform one or more desired functions. As discussed above, the circuits 104 may be customized to provide a plurality of distinct voltage sources for use in connection with other electronic devices. The receiving ports 124 of the substrate 102 function to provide electrical connection and fluid connection to a circuit coupled to the receiving port 124. As used herein, “fluid connection” means a thermal connection between a fluid passage member and the one or more power electronic circuits to provide thermal relief to the one or more power electronic circuits. In one embodiment, the receiving ports 124 are formed of copper pipe and may welded to a desired circuit. Another approach is discussed in International Patent Application Publication No. WO 2009/140672 owned by the assignee of the present invention, which is incorporated herein by reference. For example, one of the plurality of receiving ports 124 may couple to one of the plurality of connectors associated with the circuit 104. The connection may take a variety of forms. For example, the connectors and the receiving ports may be welded together. The connectors and the receiving ports may be made from a copper pipe that may be insulated with an appropriate insulating material and is positioned through at least one the receiving ports and/or connectors.

In another embodiment, one of the connectors and/or receiving ports may be conductive female coupling that mates with a corresponding receiving port or connector, for example. The connection formed between the respective receiving port and connector may be a non-latching, dry-break fluid connection. As such, the coupling of the receiving port and the connecter provide fluid and electrical connection for cooling the high current connector and reduces the size and number of interconnects required for the system. While the receiver port and connector components have been described in terms of male and/or female connections, one of ordinary skill in the art will readily appreciate the connections may be interchangeable, i.e., the connectors may be interchangeable. The embodiments shown are merely one of many possible connections and the present invention is not limited to the configuration of the connection shown. This concept could also include a flexible connector or hose with this pluggable combination connector at both ends to carry both high current and coolant between devices that use both. For example between a battery power pack and motor drive or UPS.

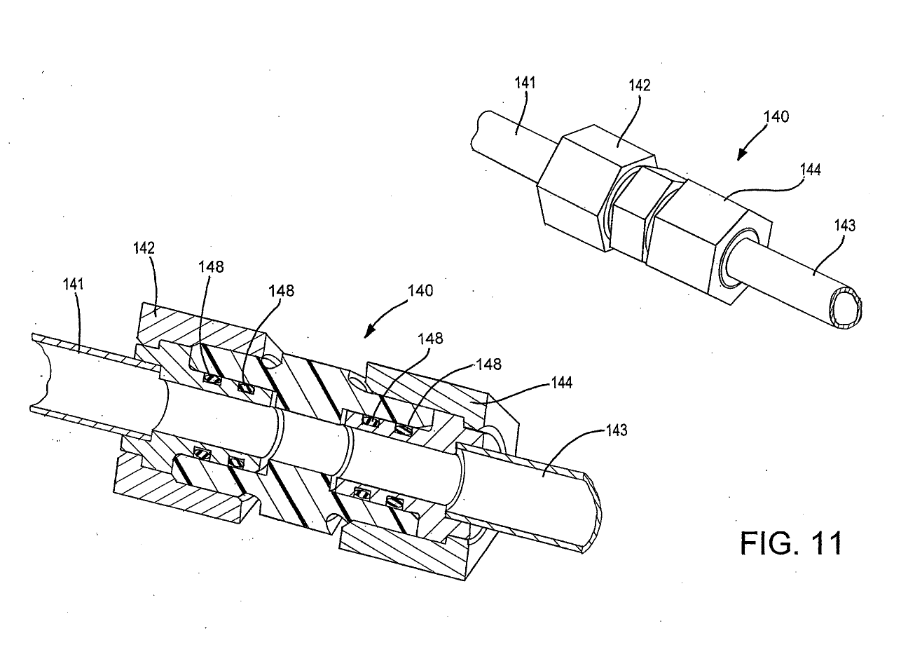

In another embodiment illustrated in FIG. 11, a dielectric union fitting 140 is illustrated. The fitting 140 includes first passage member 141 and a first nut 142 and second passage member 143 and a second nut 144. The first passage member 141 and the second passage member 143 may be coupled together by a thermoplastic element 146 that mates with nuts 142 and 144, for example. The fitting 140 provides a continuous fluid path for coupling to the fluid passage member 106 while providing an electrical discontinuity between the first passage member 141 and the second passage member 143. In cross-section view, O-rings 148 are illustrated. The O-rings 148 are illustrated in a double O-ring arrangement. Such an arrangement provides increased reliability from fluid escaping through the fitting 140. The thermoplastic element 146 allows fluid to pass through the various components even if the receiving port is not to be electrically connected to the receiving port.

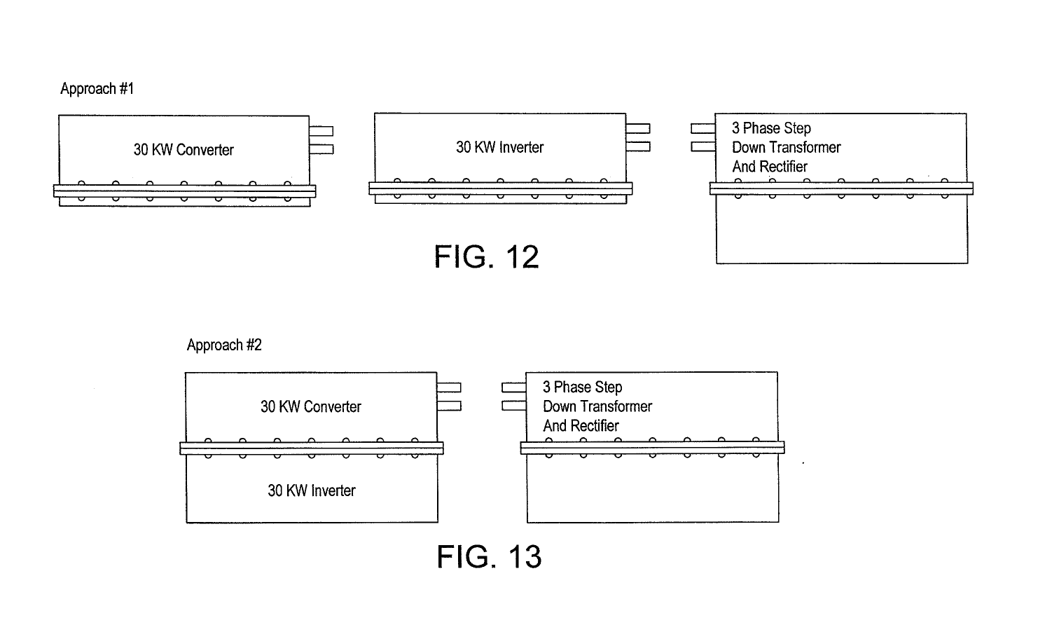

As shown in FIGS. 7-10, a housing (H) may be used to substantially encapsulate the substrate, fluid passage member and circuitry 104. The housing (H) is configured to at least partially enclose the substrate and the one or more power electronic and magnetic circuits, wherein the inlet port and the outlet port are accessible through the housing. As shown in FIGS. 7-10, the inlet port 108 and outlet port 110 may extend through the housing for connection to a cooling system. The housing (H) may also include one or more electrical connectors 130, which facilitate electrically coupling the system 100 to one or more devices. The housing may include a high voltage coupling (HVC) for coupling the power conversion system 10 to the vehicle (V), for example. Furthermore, although not shown, the housing (H) may include additional connectors to facilitate connecting multiple housings together, such that the housing will be in fluid connection with each housing. For example, as shown in FIG. 12, one or more components of the circuit 104 (e.g., the inverters 16, 18) can be packaged in a sealed cast aluminum enclosure (or other structure) and connected to another enclosure containing the transformer and rectifier. The package components can be designed to have complete symmetry and commonality for making these different configurations. Another approach, which is illustrated in FIG. 13, couples a pair of inverters in “back to back” package, which forms a complete integrated solution.

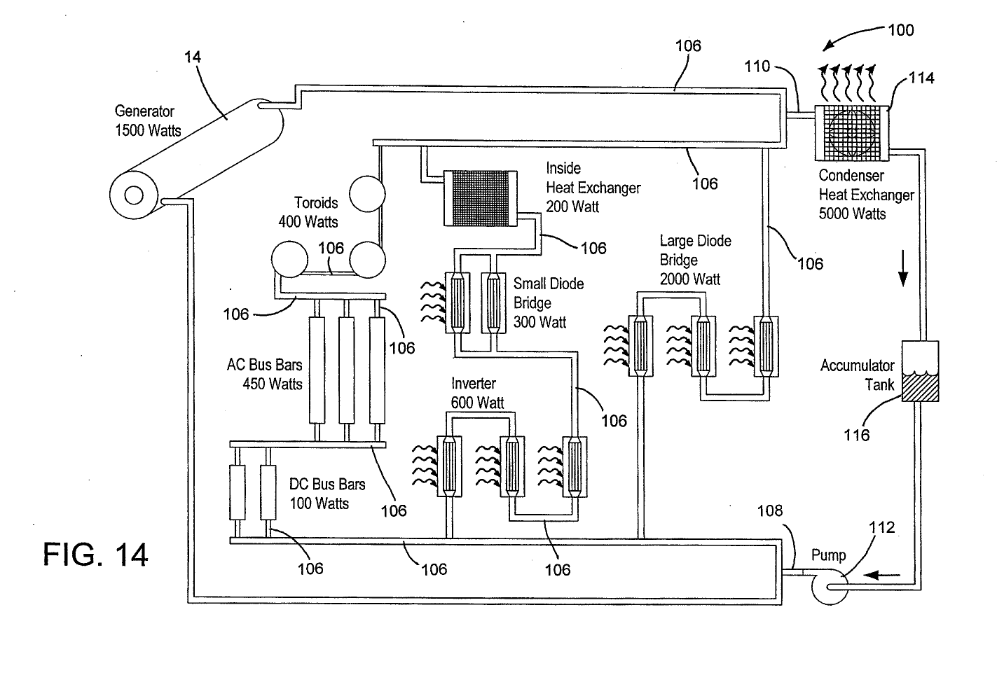

FIG. 14 illustrates an exemplary system 100 in accordance with aspects of the present. FIG. 14 provides additional detail to FIG. 5 above. Refrigerant is forced from the pump 112 through the components that form the circuitry 104. A closed-loop system is formed with the refrigerant entering inlet port 108 passing through the fluid passage member 106 and dissipating thermal effects in the components of the circuit 104. Once routed through the various components, the refrigerant is through the outlet port 110 to condenser 114, which functions to cool the refrigerant. The refrigerant is accumulated in an accumulator 116 for use by the pump 112 to continuously cool the circuitry 104 during use. The cooling fluid circulates interstitially within the substrate 102 and other passages outside of the substrate to extract heat from power electronic and magnetic circuit components.

As discussed above, the transformer 20 may be a toroid transformer. In such case, the multiple secondary windings of the toroids may be used for dual purposes: 1) connect them electrically to a combination buss plate/substrate that has the electrical buss connections such that the secondary windings are interconnected to provide maximum secondary current from the transformer; and 2) fasten the secondary connections with the shortest possible length of copper to the substrate.

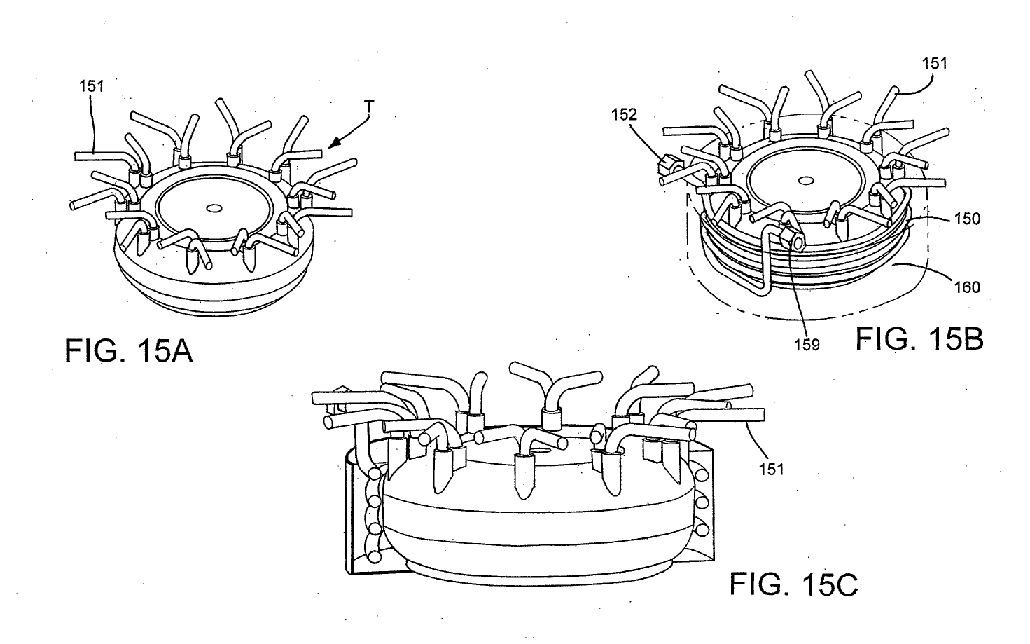

The substrate 102 has two phase cooling capability. This can be accomplished by welding the terminations (also referred to herein as connectors) to the buss plate/substrate. The substrate 102 then extracts the heat form the toroids via the secondary winding copper. Another method is to extract heat from the core of the toroid and couple it to the substrate 102 with thermal potting compound or room temperature vulcanizing (RTV) material that conducts heat. For example, in FIG. 15A, a toroid (T) is illustrated having a plurality of connectors 151 extending from the core of the toroid (T). In FIG. 15B, a fluid passage member 150 is illustrated wrapped around the toroid (T). The number of times the fluid passage member is wrapped around the toroid may be a function of the material used in the fluid passage member 150, the heat generated by the toroid (T) or any other design considerations. The fluid passage member 150 includes an inlet port 152 and an outlet port 154 for coupling the fluid passage member to the substrate 102 and/or fluid passage member 106, for example. In one embodiment, the fluid passage member is made of a copper material. FIG. 15B further illustrates a mold 160, which can be used to pour epoxy potting material in order to fix the fluid passage member 150 to the toroid. A cross-section view is illustrated in FIG. 15C.

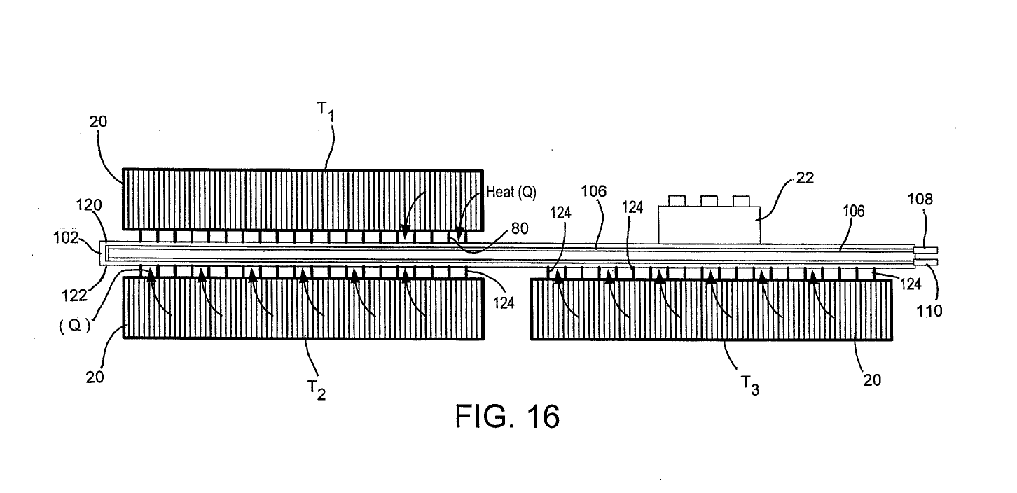

Due to the structure of the substrate 102, the rectifier 22 can be integrated into the buss plate topology for interconnect and also cooling of the rectifier 22. An exemplary rectifier 22 is a planar diode mounted to one surface 120 of the substrate 102, as illustrated in FIG. 16. As illustrated in FIG. 16, heat (Q) from the Toroids (T1-T3) and the rectifier 22 is dissipated based by the electrical terminations at the receiving ports 124 of the substrate 102. The receiving ports 124 couple the power electronics to the substrate and further provide a thermal connection between the fluid passage member and the one or more power electronics to provide thermal relief to the one or more power electronic circuits. This is illustrated as heat (Q) being drawn (illustrated by the arrows) into the substrate 102.

The disclosed embodiments illustrate exemplary systems that require substantial heat rejection. The cooling system 24 relies on two-phase cooling, which includes latent heat to transfer the heat from the power modules. In accordance with aspects of the present invention, heat is used to boil the fluid (e.g., refrigerant), which is a superior process versus the typical glycol cooling systems. In one embodiment, the refrigerant is a vaporizable dielectric refrigerant. There is a temperature/pressure relationship, such that the boiling temperature of the fluid can be set by adjusting the system pressure. Referring back to FIG. 5, the fluid boils at 67 degrees C., which will maintain the junction temperature of the insulated gate bipolar transistor (IGBT) at 108 degrees C. The fluid saturation temperature can be adjusted higher, which will provide a greater delta T to ambient temperature. This enabling technology provides the design engineer the ability to optimize the system performance without the traditional trade-offs.

Applying the subject technology to hybrid/electric vehicles would bring the following benefits: Packaging: It is anticipated that the above described systems may incorporated and packaged for a military grade power system. The inverters can be packaged in a sealed cast aluminum enclosure (or other type of enclosure) and connected to another enclosure containing the transformer and rectifier, for example. The package components can be designed to have complete symmetry and commonality for making these different configurations. An alternative approach may couple components (e.g., a pair of inverters in “back to back” package, which forms a complete integrated solution. Still another approach would be to incorporate all of the electronic and magnetic components within a single housing.

There are a variety of potential system advantages with the technology of the present disclosure. Such advantages include: better power quality; integrated cooling technology with high voltage solution; flexibility in creating multiple power supply voltages from single source; stable power generating capability at varying RPM. Distributed system or consolidated system configuration to accommodate different footprint requirements. Higher efficiency compared to DC generator implementation 90% versus 80-85%; results in fuels savings in the theater estimated at $120-150 USD per gallon delivered; higher mean time between failures of the power module due to less thermal cycling; no maintenance; no replacement filters; no biocides, etc.

Other advantages for the cooling system tied to the electronics system: the pump is reduced from 20 gpm to 3 gpm using this technology. The pump is smaller using less parasitic power increasing vehicle range. The system is isothermal simplifying plumbing of cooling electronics. The fluid is a dielectric & will not harm electronics in the event of a leak. The system may be hermetic, such that no end user maintenance is required. No silicon de-rating is necessary using this combination. The system has the ability to dissipate heat in a high ambient environment (70-75 degrees Celsius). A smaller condenser, smaller fans, less parasitic power draw can be used. And, there are no freezing issues.

Although the principles, embodiments and operation of the present invention have been described in detail herein, this is not to be construed as being limited to the particular illustrative forms disclosed. They will thus become apparent to those skilled in the art that various modifications of the embodiments herein can be made without departing from the spirit or scope of the invention.

What is claimed is:

1. A power conversion system (10, 100) comprising:
a substrate (102) including a front surface (120), a back surface (122), and a fluid passage member (106) disposed at least partially between the front surface and the back surface, wherein the fluid passage member includes an inlet port (108) for receiving fluid and an outlet port (110) for outputting fluid, wherein the substrate includes a plurality of receiving ports (124) for coupling one or more circuits to the substrate and the receiving ports are coupled to the fluid passageway; and
one or more power electronic circuits (104), wherein the one or more power electronic circuits include a plurality of connectors that are configured to be received by the receiving ports of the substrate such that the plurality of connectors are configured to provide an electrical connection between the one or more power electronic circuits and establish a thermal connection between the fluid passage member and the one or more power electronic circuits to provide thermal relief to the one or more power electronic circuits.

2. The power conversion system of claim 1, further including a housing (H) configured to at least partially enclose the substrate and the one or more power electronic circuits, wherein the inlet port and the outlet port are accessible through the housing.

3. The power conversion system of any one of claims 1-2, wherein the one or more power electronic circuits include a magnetic circuit.

4. The power conversion system of any one of claims 1-3, wherein the one or more power electronic circuits are operable to convert a high voltage, low current signal to a plurality of lower voltage signals (22, 30, 36) having distinct voltage and/or current characteristics from the high voltage, low current signal.

5. The power conversion system of any one of claims 1-4, further including at least one connector (130) accessible through the housing for at least one of the plurality of lower voltage signals.

6. The power conversion system of claim 5 further including at least one connector accessible through the housing for each of the at least one of the plurality of lower voltage signals.

7. The power conversion system of any one of claims 1-6, further including a cooling system (100) including a pump (112) for forcing refrigerant through the fluid passageway of the substrate and the plurality of connectors for providing thermal relief to the one or more power electronic and magnetic circuits.

8. The power conversion system of claim 7, further including the cooling system cooling each of the power electronic and/or magnetic circuits.

9. The power conversion system of claim 7, wherein the refrigerant is routed through each of the power electronic and/or magnetic circuits to reduce thermal operating temperatures for each of the power electronic and magnetic circuits.

10. The power conversion system of claim 7, wherein the refrigerant is a vaporizable dielectric refrigerant.

11. The power conversion system of claim 7, wherein the cooling system includes a condenser (114) in fluid communication with the pump, wherein the refrigerant passes through the condenser to reject heat and the refrigerant is returned to the pump.

12. The power conversion system of any one of claims 1-11, wherein at least one of the plurality of connectors are coupled to one of the plurality of receivers by a dry-break connection.

13. The power conversion system of any one of claims 1-12, wherein at least one of the plurality of connectors are coupled to one of the plurality of receivers by a non-latching connection.

14. The power conversion system of any one of claims 1-13, wherein at least one of the plurality of connectors are coupled to one of the plurality of receivers by a plug and socket connection.

15. The power conversion system of claim 14, wherein each plug and socket connection is formed at least in part as a hollow tube, wherein at least a portion of the hollow tube is conductive along a length of the hollow tube and is in fluid communication with the fluid passageway.

16. The power conversion system of any one of claims 1-15, wherein the one or more power electronic and/or magnetic circuits include a magnet generator (14) for generating a high voltage alternating current output; a first inverter (16) that receives the high voltage alternating current output and outputs a stable direct current high voltage signal; a second inverter (18) coupled to the first inverter, wherein the second inverter receives the stable direct current high voltage signal and converts the signal to a driving alternating current signal for driving a transformer (20); and a bridge rectifier (22) coupled to the transformer, wherein the bridge rectifier output a low voltage direct current signal.

17. The power conversion system of any one of claims 1-16, wherein the power conversion system is operable to convert a signal received from an alternator (14) of a vehicle (V) to a desired lower voltage signal.

18. The power conversion system of any one of claims 1-17, wherein a filter (19) is coupled between the second inverter and the transformer for smoothing the driving alternating current signal.

19. The power conversion system of any one of claims 1-18, further including a third inverter coupled (32) to the first inverter, wherein the third inverter is coupled to a transformer for generating a second low voltage high current signal.

20. The power conversion system of claim 1, wherein the one or more power electronic and magnetic circuits include a first diode bridge rectifier (16) for converting high voltage alternating current output by an alternator (14) to a high voltage direct current signal, an inverter (18) coupled to the first diode bridge rectifier to convert the direct current signal to alternating current, a transformer (20) coupled to the inverter to output an intermediary low voltage signal; and a second diode bridge rectifier (22) for outputting a low voltage direct current signal.

21. The power conversion system of claim 20, wherein the transformer is a toroid transformer.

22. The power conversion system of claim 21, wherein the toroid transformer is a 400 hertz transformer.

23. The power conversion system of claim 22, wherein the low voltage direct current signal is 28 V.

24. The power conversion system of any one of claims 20-23 further including a battery (38) coupled to the second bridge rectifier, wherein the battery stores the low voltage direct current signal received by the second diode bridge rectifier.

25. The power conversion system of any one of claims 20-24, further including a charge control feedback loop (40) between the inverter (18) and the second diode bridge rectifier (22) for controlling voltage regulation.

26. The power conversion system of any one of claims 20-25, wherein the direct current signal output by the first diode bridge rectifier is dependent on the input signals received by the first diode bridge rectifier.

27. The power conversion system of any one of claims 20-26, further including a second inverter (32) coupled to the first bridge rectifier, wherein the second inverter is coupled to a transformer (36) for generating a second low voltage high current signal.

28. The power conversion system of claim 27, wherein the direct current signal output by the second inverter is independent on input received from first diode bridge rectifier.

29. A method for manufacturing a portable power supply, the method comprising:
forming a fluid passageway with a fluid passage member (106) housed at least partially within a substrate (102) having a front surface (120) and a back surface (122), wherein the fluid passage member includes an inlet port (108) for receiving fluid and an outlet port (110) for outputting fluid and the substrate includes a plurality of receiving ports that are coupled to the fluid passageway;
securing one or more power electronic circuits (104) to at least one of the receiving ports, wherein the electronic and magnetic circuits form an electrical connection and a thermal connection between the fluid passage member and the one or more power electronic circuits to provide thermal relief to the one or more power electronic circuits; and
placing the substrate containing the fluid passageway and the one or more power electronic circuits within a housing (H) that is configured to at least partially enclose the substrate and the one or more power electronic and magnetic circuits, wherein the inlet port and the outlet port are accessible through the housing.

30. The method of claim 29, further comprising coupling a cooling system (100) between the inlet port and outlet port, wherein the cooling system is operable to force refrigerant through the fluid passageway of the substrate and the plurality of receiving ports of the power electronic circuits for providing thermal relief to the one or more power electronic circuits.

31. The method of claim 30, wherein the refrigerant is routed through each of the power electronic and magnetic circuits and a condenser to reduce thermal operating temperatures for each of the power electronic circuits.

32. A method for converting power, the method comprising:
receiving a high voltage, low current signal from a source (12);
converting the high voltage, low current signal through one or more power electronic and magnetic circuits (104) to a plurality of lower voltage signals having distinct voltage and/or current characteristics from the high voltage, low current signal, wherein the one or more power electronic and magnetic circuits are coupled to a substrate (102) having a front surface (120), a back surface (122), and a fluid passage member (106) disposed at least partially between the front surface and the back surface, wherein the fluid passage member includes an inlet port for receiving fluid and an outlet port for outputting fluid, wherein the substrate includes a plurality of receiving ports (124) for coupling the power electronic and magnetic circuits to the substrate and the receiving ports are coupled to the fluid passageway; and wherein the one or more power electronic circuits include a plurality of connectors that are configured to be received by the receiving ports of the substrate such that the plurality of connectors are configured to provide an electrical connection between the one or more power electronic circuits and establish a thermal connection between the fluid passage member and the one or more power electronic to provide thermal relief to the one or more power electronic circuits; and
cooling the one or more power electronic circuits by providing a cooling system (100) utilizing a vaporizable dielectric refrigerant, wherein a pump forces vaporizable dielectric refrigerant through the fluid passageway of the substrate and the plurality of connectors.

33. The method of claim 32, wherein the refrigerant is routed through each of the power electronic circuits and a condenser to reduce thermal operating temperatures for each of the power electronic circuits.
